(19) United States
(12) Patent Application Publication
(10) Pub. No.: US 2025/0275422 A1
(43) Pub. Date: Aug. 28, 2025

(54) DISPLAY DEVICE AND METHOD OF MANUFACTURING THE SAME

(71) Applicant: Samsung Display Co., LTD., Yongin-si (KR)

(72) Inventors: So Young OH, Yongin-si (KR); Jong Woo KIM, Yongin-si (KR); Hyun Sup YOON, Yongin-si (KR); Woo Suk JUNG, Yongin-si (KR); Jae Heung HA, Yongin-si (KR)

(21) Appl. No.: 18/827,545

(22) Filed: Sep. 6, 2024

(30) Foreign Application Priority Data
Feb. 28, 2024 (KR) 10-2024-0028879

(51) Int. Cl. H10K 59/80; H10K 102/00

(52) U.S. Cl. CPC H10K 59/873; H10K 2102/351

(57) ABSTRACT

A display device includes: a light emitting element; and an encapsulation layer on the light emitting element, wherein the encapsulation layer includes: a first encapsulation layer; a second encapsulation layer on the first encapsulation layer; a third encapsulation layer on the second encapsulation layer; and a fourth encapsulation layer on the third encapsulation layer, wherein the third encapsulation layer includes a void.

### CROSS-REFERENCE TO RELATED APPLICATION

The present application claims priority to and the benefit of Korean Patent Application No. 10-2024-0028879, filed on Feb. 28, 2024, in the Korean Intellectual Property Office, the entire disclosure of which is incorporated herein by reference.

### BACKGROUND

### 1. Field

Aspects of some embodiments of the present disclosure relate to a display device and a method of manufacturing the same.

### 2. Description of the Related Art

As information technology develops, the importance of display devices as a connection medium between users and information is being emphasized.

A display device may include a light emitting element and an encapsulation layer. The encapsulation layer may cover the light emitting element and relatively reduce the risk of impurities (for example, moisture) penetrating into the display device from outside. Accordingly, when the encapsulation layer is not properly formed, a defect rate of the display device may increase.

The above information disclosed in this Background section is only for enhancement of understanding of the background and therefore the information discussed in this Background section does not necessarily constitute prior art.

### SUMMARY

Aspects of some embodiments of the present disclosure include a display device that may be capable of relatively reducing a defect rate and a method of manufacturing the same.

A display device according to some embodiments of the present disclosure may include a light emitting element and an encapsulation layer on the light emitting element. According to some embodiments, the encapsulation layer may include a first encapsulation layer; a second encapsulation layer on the first encapsulation layer; a third encapsulation layer on the second encapsulation layer; and a fourth encapsulation layer on the third encapsulation layer, and the third encapsulation layer may include a void.

According to some embodiments, the second encapsulation layer may include an organic material, and the first encapsulation layer, the third encapsulation layer, and the fourth encapsulation layer may include an inorganic material.

According to some embodiments, the second encapsulation layer may include a base portion and a protrusion protruding from the base portion in a normal direction of a plane in which the display device is located.

According to some embodiments, the display device may further include an opening adjacent to the protrusion.

According to some embodiments, the second encapsulation layer may include an upper surface having uneven portions.

According to some embodiments, at least a portion of the third encapsulation layer may be within the opening, and the void is within the opening.

According to some embodiments, the third encapsulation layer may have a density higher than or equal to a density of the fourth encapsulation layer.

According to some embodiments, the fourth encapsulation layer may have a greater thickness than the third encapsulation layer.

According to some embodiments, the third encapsulation layer may have a thickness of about 5 Å to about 15 Å.

According to some embodiments, the third encapsulation layer overlapping a side surface of the protrusion may have an uneven thickness.

According to some embodiments, the first encapsulation layer may be in contact with the second encapsulation layer, the second encapsulation layer may be in contact with the third encapsulation layer, and the third encapsulation layer may be in contact with the fourth encapsulation layer.

According to some embodiments, the fourth encapsulation layer may not be filled into the void.

A method of manufacturing a display device according to some embodiments of the present disclosure may include forming a light emitting element layer and forming an encapsulation layer on the light emitting element layer. According to some embodiments, the forming the encapsulation layer may include forming a first encapsulation layer; forming a second encapsulation layer on the first encapsulation layer; forming a third encapsulation layer on the second encapsulation layer; and forming a fourth encapsulation layer on the third encapsulation layer, and the forming the third encapsulation layer may include forming a void in the third encapsulation layer.

According to some embodiments, the second encapsulation layer may include an organic material, the first encapsulation layer, the third encapsulation layer, and the fourth encapsulation layer may include an inorganic material. According to some embodiments, the first encapsulation layer may be in contact with the second encapsulation layer, the second encapsulation layer may be in contact with the third encapsulation layer, and the third encapsulation layer may be in contact with the fourth encapsulation layer.

According to some embodiments, the forming the second encapsulation layer may include forming a base encapsulation layer on the first encapsulation layer; arranging a mask on the base encapsulation layer; and exposing the base encapsulation layer to plasma. According to some embodiments, at least a portion of an upper surface of the base encapsulation layer may be etched by the plasma.

According to some embodiments, the base encapsulation layer may be etched by the plasma to form a protrusion and an opening.

According to some embodiments, the base encapsulation layer may be etched by the plasma so that an upper surface of the second encapsulation layer has uneven portions.

According to some embodiments, the void may be within the opening.

According to some embodiments, the forming the third encapsulation layer may include depositing the third encapsulation layer on the second encapsulation layer, and the third encapsulation layer may be deposited at a different rate in some areas than in other areas.

According to some embodiments, the third encapsulation layer may have a thickness of about 5 Å to about 15 Å.

### BRIEF DESCRIPTION OF THE DRAWINGS

The accompanying drawings, which are included to provide a further understanding of embodiments according to the present disclosure, and are incorporated in and constitute a part of this specification, illustrate aspects of some embodiments of the present disclosure, and, together with the description, serve to explain aspects of some embodiments of the present disclosure.

FIG. 1 is a plan view schematically illustrating a display device according to some embodiments.

FIG. F 2 is a cross-sectional view schematically illustrating the display device according to some embodiments.

FIG. 3 is a cross-sectional view schematically illustrating an encapsulation layer according to some embodiments.

FIG. 4 is a schematic cross-sectional view enlarging an area “S” of FIG. 3.

FIG. 5 is a flow chart illustrating aspects of a method of manufacturing of a display device according to some embodiments.

FIG. 6 is a cross-sectional view schematically illustrating further details of the method of manufacturing the display device according to operations S100 and S200.

FIG. 7 is a flow chart illustrating further details of an operation S300 of FIG. 5.

FIGS. 8 to 13 are cross-sectional views schematically illustrating aspects of the method of manufacturing the display device according to some embodiments.

### DETAILED DESCRIPTION

As the present disclosure allows for various changes and numerous embodiments, particular embodiments will be illustrated in the drawings and described in detail in the written description. However, this is not intended to limit scope of embodiments according to the present disclosure to particular modes of practice, and it is to be appreciated that all changes, equivalents, and substitutes that do not depart from the spirit and technical scope of the present disclosure are encompassed in the present disclosure.

It will be understood that, although the terms “first”, “second”, etc. may be used herein to describe various elements, these elements should not be limited by these terms. These terms are only used to distinguish one element from another element. For instance, a first element discussed below could be termed a second element without departing from the scope of the present disclosure. Similarly, the second element could also be termed the first element. In the disclosure, the singular expressions are intended to include the plural expressions as well, unless the context clearly indicates otherwise.

It will be further understood that the terms “comprise”, “include”, “have”, etc. used in the present disclosure, specify the presence of stated features, integers, steps, operations, elements, components, or combinations of them but do not preclude the presence or addition of one or more other features, integers, steps, operations, elements, components, or combinations thereof. In addition, when a first part such as a layer, film, region, plat, etc. is “on” a second part, the first part may be not only “directly on” the second part but a third part may intervene between them. Furthermore, in the present disclosure, when a first part such as a layer, film, region, plat, etc. is formed on a second part, a direction in which the first part is formed is not limited to an upper direction of the second part, but may include a side or a lower direction of the second part. To the contrary, when a first part such as a layer, film, region, plat, etc. is “under” a second part, the first part may be not only “directly under” the second part but a third part may intervene between them.

The present disclosure relates to a display device and a method of manufacturing the same. Hereinafter, a display device and a method of manufacturing the same according to embodiments will be described with reference to the accompanying drawings.

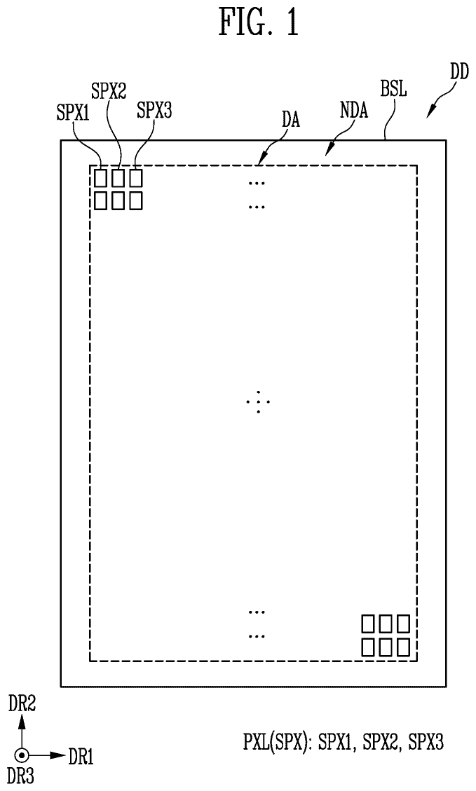

FIG. 1 is a plan view schematically illustrating a display device according to some embodiments.

Referring to FIG. 1, a display device DD may be configured to emit light. The display device DD may include a light emitting element LD (see FIG. 2). According to some embodiments, the display device DD may be a device that displays moving images (e.g., video images) or still images (e.g., static images). The display device DD may be used as a display screen for various electronic devices such as televisions, laptops, monitors, billboards, and internet of things (IoT) devices, as well as portable electronic devices such as mobile phones, smart phones, tablet personal computers, smart watches, watch phones, mobile communication terminals, electronic notebooks, e-books, portable multimedia players (PMPs), navigation devices, and ultra mobile PCs (UMPCs). However, the application field of the display device DD is not limited to the above-listed specific examples.

The display device DD may be formed in the form of a rectangular flat plate having a short side in a first direction DR1 and a long side in a second direction DR2 that intersects the first direction DR1. A corner portion where the short side in the first direction DR1 and the long side in the second direction DR2 meet may be rounded to have a curvature (e.g., a set or predetermined curvature) or may be formed at a right angle. The planar shape of the display device DD is not limited to a square shape or rectangular shape, and may be formed in another polygonal shape, an irregular shape, or a round shape such as a circle or oval. The display device DD may be formed flat, but embodiments according to the present disclosure are not limited thereto. For example, the display device DD may include curved portions formed at left and right ends and having a constant curvature or a changing curvature. In addition, the display device DD may be flexible so that it can be curved, bent, folded, or rolled. For example, according to some embodiments, the display device DD may be a flexible display device.

In the present disclosure, the first direction DR1 may be a row direction of pixels PXL and may be a “horizontal” direction. The second direction DR2 may be a column direction of the pixels PXL. A third direction DR3 may be a display direction of the display device DD or a normal direction of a plane in which a base layer BSL is located.

The display device DD may include a display area DA and a non-display area NDA. The non-display area NDA may refer to an area other than the display area DA. The non-display area NDA may surround at least a portion of the display area DA.

The display area DA may refer to an area where the pixels PXL are located. The non-display area NDA may refer to an area where the pixels PXL are not located. A driving circuit unit, wirings, and pads connected to the pixels PXL of the display area DA may be located in the non-display area NDA.

According to some embodiments, a pixel PXL (or sub-pixels SPX) may include a first sub-pixel SPX1, a second sub-pixel SPX2, and a third sub-pixel SPX3. At least one first sub-pixel SPX1, second sub-pixel SPX2, and third sub-pixel SPX3 may form one pixel unit PXU capable of emitting light of various colors. FIG. 1 shows an example in which each pixel PXL includes three sub-pixels SPX1, SPX2, and SPX3, that is, the first sub-pixel SPX1, the second sub-pixel SPX2, and the third sub-pixel SPX3, but embodiments of the present specification are not limited thereto.

According to some embodiments, the pixel PXL (or sub-pixels SPX) may be arranged according to a stripe or PENTILET arrangement structure. However, the present disclosure is not necessarily limited thereto.

The first sub-pixel SPX1 may emit first light, the second sub-pixel SPX2 may emit second light, and the third sub-pixel SPX3 may emit third light. Here, the first light may be light in a red wavelength band, the second light may be light in a green wavelength band, and the third light may be light in a blue wavelength band. The red wavelength band may be a wavelength band of 600 nm to 750 nm (or approximately 600 nm to 750 nm), the green wavelength band may be a wavelength band of 480 nm to 560 nm (or approximately 480 nm to 560 nm), and the blue wavelength band may be a wavelength band of 370 nm to 460 nm (or approximately 370 nm to 460 nm), but embodiments of the present specification are not limited thereto.

Each of the first sub-pixel SPX1, the second sub-pixel SPX2, and the third sub-pixel SPX3 may be a light emitting element that emits light and may include an inorganic light emitting element including an inorganic semiconductor or an organic light emitting element (OLED). The present disclosure is not limited to particular examples. Hereinafter, for convenience of description, the description will be based on embodiments in which each of the first sub-pixel SPX1, the second sub-pixel SPX2, and the third sub-pixel SPX3 includes an organic light emitting element.

FIG. 2 is a cross-sectional view schematically illustrating the display device according to some embodiments.

The display device DD may include a base layer BSL, a pixel circuit layer PCL, and a display element layer DPL.

The base layer BSL may provide an area where the pixel circuit layer PCL and the display element layer DPL are located. The base layer BSL may form (or constitute) a base member of the pixel PXL. The base layer BSL may be a rigid or flexible substrate or film, but embodiments according to the present disclosure are not limited to specific examples.

The pixel circuit layer PCL may be located on the base layer BSL. The pixel circuit layer PCL may include a buffer film BFL, a transistor TR, a gate insulating film GI, a first interlayer insulating film ILD1, a second interlayer insulating film ILD2, a connection pattern BCP, a power source line PLL, a passivation film PSV, and a contact portion CNT.

The buffer film BFL may be located on the base layer BSL. The buffer film BFL may prevent or relatively reduce diffusion of impurities or contaminants from outside. The buffer film BFL may include at least one of metal oxides such as silicon nitride (SiNx), silicon oxide (SiOx), silicon oxynitride (SiOxNy), or aluminum oxide (AIOx).

The transistor TR may be a thin film transistor. According to some embodiments, the transistor TR may be a driving transistor. The transistor TR may be electrically connected to the light emitting element LD. The transistor TR may be electrically connected to the connection pattern BCP.

The transistor TR may include an active layer ACT, a first transistor electrode TE1, a second transistor electrode TE2, and a gate electrode GE.

The active layer ACT may refer to a semiconductor layer. The active layer ACT may be located on the buffer film BFL. The active layer ACT may include at least one of polysilicon, low temperature polycrystalline silicon (LTPS), amorphous silicon, or oxide semiconductor.

The active layer ACT may include a first contact region in contact with the first transistor electrode TE1 and a second contact region in contact with the second transistor electrode TE2. The first contact region and the second contact region may be a semiconductor pattern doped with impurities. A region between the first contact region and the second contact region may be a channel region. The channel region may be an intrinsic semiconductor pattern that is not doped with impurities.

The gate electrode GE may be located on the gate insulating film GI. The position of the gate electrode GE may correspond to the position of the channel region of the active layer ACT. For example, the gate electrode GE may be located on the channel region of the active layer ACT with the gate insulating film GI interposed therebetween.

The gate insulating film GI may be located on the active layer ACT. The gate insulating film GI may include an inorganic material. According to one example, the gate insulating film GI may include at least one of silicon nitride (SiNx), silicon oxide (SiOx), silicon oxynitride (SiOxNy), or aluminum oxide (AIOx).

The first interlayer insulating film ILD1 may be positioned on the gate electrode GE. Like the gate insulating film GI, the first interlayer insulating film ILD1 may include at least one of silicon nitride (SiNx), silicon oxide (SiOx), silicon oxynitride (SiOxNy), or aluminum oxide (AIOx).

The first transistor electrode TE1 and the second transistor electrode TE2 may be positioned on the first interlayer insulating film ILD1. The first transistor electrode TE1 may penetrate the gate insulating film GI and the first interlayer insulating film ILD1 to contact the first contact region of the active layer ACT, and the second transistor electrode TE2 may penetrate the gate insulating film GI and the first interlayer insulating film ILD1 to contact the second contact region of the active layer ACT. According to one example, the first transistor electrode TE1 may be a drain electrode, and the second transistor electrode TE2 may be a source electrode, but the present disclosure is not limited thereto.

The second interlayer insulating film ILD2 may be positioned on the first transistor electrode TE1 and the second transistor electrode TE2. Like the first interlayer insulating film ILD1 and the gate insulating film GI, the second interlayer insulating film ILD2 may include an inorganic material. The inorganic material may include at least one of materials constituting the first interlayer insulating film ILD1 and/or the gate insulating film GI, for example, silicon nitride (SiNx), silicon oxide (SiOx), silicon oxynitride (SiOxNy), or aluminum oxide (AIOx).

The connection pattern BCP may be located on the second interlayer insulating film ILD2. The connection pattern BCP may be connected to the first transistor electrode TE1 through a contact hole penetrating the second interlayer insulating film ILD2. The connection pattern BCP may be electrically connected to a first electrode ELT1 through the contact portion CNT formed in the passivation film PSV.

The power source line PLL may be located on the second interlayer insulating film ILD2. The power source line PLL may be electrically connected to a second electrode ELT2 through another contact portion formed in the passivation film PSV.

The passivation film PSV may be positioned on the second interlayer insulating film ILD2. The passivation film PSV may cover the connection pattern BCP and power source line PLL. The passivation film PSV may be provided in a form including an organic insulating film, an inorganic insulating film, or an organic insulating film located on the inorganic insulating film, but the present disclosure is not limited thereto. According to some embodiments, the contact portion CNT connected to an area of the connection pattern BCP and another contact portion connected to an area of the power source line PLL may be formed in the passivation film PSV.

The display element layer DPL may be located on the pixel circuit layer PCL. The display element layer DPL may include the first electrode ELT1, the light emitting element LD, a pixel defining layer PDL, the second electrode ELT2, and an encapsulation layer TFE.

According to some embodiments, the light emitting element LD may be located in an area defined by the pixel defining layer PDL. One side of the light emitting element LD may be connected to the first electrode ELT1, and the other side of the light emitting element LD may be connected to the second electrode ELT2.

Here, the first electrode ELT1 may be an anode electrode for the light emitting element LD, and the second electrode ELT2 may be a common electrode (or cathode electrode) for the light emitting element LD. According to some embodiments, the first electrode ELT1 and the second electrode ELT2 may include a conductive material. For example, the first electrode ELT1 may include a conductive material with reflective properties, and the second electrode ELT2 may include a transparent conductive material, but embodiments according to the present disclosure are not necessarily limited thereto.

According to some embodiments, the light emitting element LD may have a multilayer thin film structure including a light generation layer. The light emitting element LD may have a hole injection layer that injects holes, a hole transport layer that has excellent hole transport properties and suppresses the movement of electrons that are not combined in the light generation layer to increase the chance of recombination of holes and electrons, the light generation layer that emits light by recombination of injected electrons and holes, a hole blocking layer to suppress the movement of holes that are not combine in the light generation layer, an electron transport layer to smoothly transport electrons to the light generation layer, and an electron injection layer that injects electrons. The light emitting element LD may emit light based on electrical signals provided from the first electrode ELT1 and the second electrode ELT2.

The pixel defining layer PDL may define the position where the light emitting element LD implemented with an organic light emitting diode is located. The pixel defining layer PDL may include an organic material. According to one example, the pixel defining layer PDL may include at least one of an acryl resin, an epoxy resin, a phenol resin, a polyamide resin, or a polyimide resin, but embodiments according to the present disclosure are not limited thereto.

The encapsulation layer TFE may be located on the second electrode ELT2. The encapsulation layer TFE may relatively reduce step differences generated by the light emitting element LD and the pixel defining layer PDL. The encapsulation layer TFE may include a plurality of insulating films covering the light emitting element LD.

The encapsulation layer TFE according to some embodiments of the present disclosure may increase the reliability of the display device DD (for example, may relatively reduce a defect rate of the display device DD). For example, the encapsulation layer TFE may relatively reduce the risk of cracks growing within the encapsulation layer TFE and relieve stress applied to the encapsulation layer TFE when the display device DD is bent.

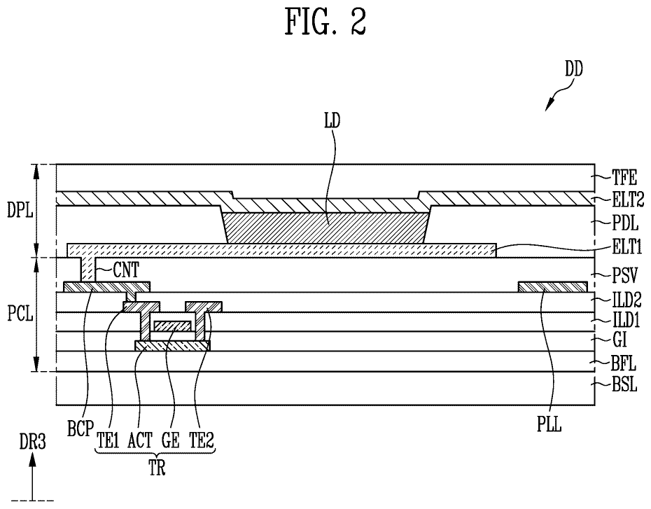

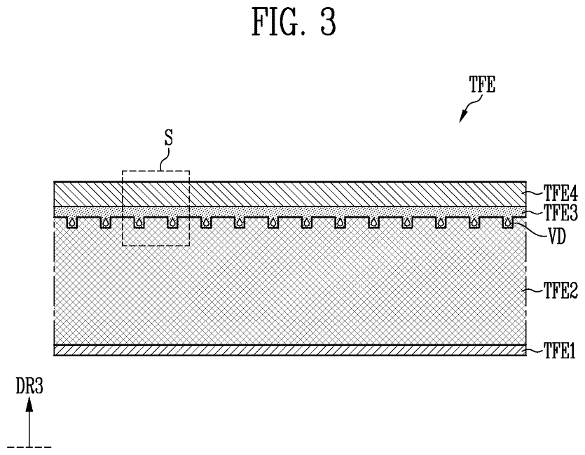

Details regarding the encapsulation layer TFE will be described later with reference to FIGS. 3 and 4.

FIG. 3 is a cross-sectional view schematically illustrating an encapsulation layer according to some embodiments. FIG. 4 is a schematic cross-sectional view enlarging an area S of FIG. 3.

Referring to FIGS. 3 and 4, the encapsulation layer TFE may include a multilayer structure. For example, the encapsulation layer TFE may include a first encapsulation layer TFE1, a second encapsulation layer TFE2, a third encapsulation layer TFE3, and a fourth encapsulation layer TFE4. According to some embodiments, the encapsulation layer TFE may have a structure in which the first encapsulation layer TFE1, the second encapsulation layer TFE2, the third encapsulation layer TFE3, and the fourth encapsulation layer TFE4 are sequentially stacked on the second electrode ELT2.

The first encapsulation layer TFE1 may be located on the second electrode ELT2. The first encapsulation layer TFE1 may entirely cover the second electrode ELT2.

The first encapsulation layer TFE1 may have a flat surface. For example, an upper surface of the first encapsulation layer TFE1 may be flat. Hereinafter, in the present disclosure, an upward direction may be defined as the third direction DR3. The upper surface of the first encapsulation layer TFE1 may be a surface in contact with the second encapsulation layer TFE2.

The first encapsulation layer TFE1 may have a generally uniform thickness. The first encapsulation layer TFE1 may have a thinner thickness than the second encapsulation layer TFE2. The first encapsulation layer TFE1 may have a thinner thickness than the fourth encapsulation layer TFE4.

The first encapsulation layer TFE1 may include an inorganic material. For example, the first encapsulation layer TFE1 may include at least one of silicon nitride (SiNx), silicon oxide (SiOx), silicon oxynitride (SiOxNy), or aluminum oxide (AIOx).

The second encapsulation layer TFE2 may be located on the first encapsulation layer TFE1. The second encapsulation layer TFE2 may entirely cover the first encapsulation layer TFE1. The second encapsulation layer TFE2 may be in contact with the first encapsulation layer TFE1.

The second encapsulation layer TFE2 may have a flat surface. For example, a lower surface of the second encapsulation layer TFE2 may be flat. Hereinafter, in the present disclosure, a downward direction may be defined as a direction opposite to the third direction DR3. The lower surface of the second encapsulation layer TFE2 may face the upper surface of the first encapsulation layer TFE1. The lower surface of the second encapsulation layer TFE2 may be a surface in contact with the first encapsulation layer TFE1.

The second encapsulation layer TFE2 may have a surface that is not generally flat. An upper surface of the second encapsulation layer TFE2 may not be generally flat. The upper surface of the second encapsulation layer TFE2 may have uneven portions. For example, at least a portion of the upper surface of the second encapsulation layer TFE2 may protrude.

The second encapsulation layer TFE2 may include a base portion BSU and a protrusion PRU. A portion protruding from the upper surface of the second encapsulation layer TFE2 may be defined as the protrusion PRU. The second encapsulation layer TFE2 excluding the protrusion PRU may be defined as the base portion BSU. The protrusion PRU may protrude in one direction (for example, the third direction DR3). For example, the protrusion PRU may protrude from the base portion BSU in a normal direction on a plane where the display device DD is located.

The protrusion PRU may define an opening H. The opening H may be located adjacent to (for example, on a side of) the protrusion PRU. The opening H may be located between protrusions PRU. A plurality of openings H may be provided. The plurality of openings H may be spaced apart from each other at generally uniform intervals. However, the present disclosure is not limited thereto.

According to some embodiments, the protrusion PRU may have a square cross-section when viewed in cross section. According to some embodiments, the protrusion PRU may have a mesh pattern shape when viewed on a plane. However, the present disclosure is not limited thereto, and the protrusion PRU may have a cross-section of various shapes.

Each of the base portion BSU and the protrusion PRU may have a generally uniform thickness. The second encapsulation layer TFE2 may have a greater thickness than the third encapsulation layer TFE3. In this specification, the thickness of the second encapsulation layer TFE2 may be defined as an average thickness of the second encapsulation layer TFE2. The thickness of the second encapsulation layer TFE2 may include the base portion BSU and the protrusion PRU.

The second encapsulation layer TFE2 may include an organic material. For example, the second encapsulation layer TFE2 may include at least one of an acryl resin, an epoxy resin, a phenol resin, a polyamide resin, or a polyimide resin.

The third encapsulation layer TFE3 may be located (for example, directly located) on the second encapsulation layer TFE2. At least a portion of the third encapsulation layer TFE3 may be located in the opening H. The third encapsulation layer TFE3 may entirely cover the second encapsulation layer TFE2. The third encapsulation layer TFE3 may be in contact with the second encapsulation layer TFE2. For example, the third encapsulation layer TFE3 may be directly adjacent to the protrusion PRU. At least a portion of the third encapsulation layer TFE3 may overlap a portion of the second encapsulation layer TFE2 (for example, the protrusion PRU) in a plane direction in which the base layer BSL is located (for example, a plane direction defined by the first direction DR1 and the second direction DR2).

The third encapsulation layer TFE3 may have a flat surface. For example, an upper surface of the third encapsulation layer TFE3 may be flat. The upper surface of the third encapsulation layer TFE3 may be a surface in contact with the fourth encapsulation layer TFE4. The third encapsulation layer TFE3 may have a surface that is not flat. For example, a lower surface of the third encapsulation layer TFE3 may not be flat. The lower surface of the third encapsulation layer TFE3 may have uneven portions. The lower surface of the third encapsulation layer TFE3 may be a surface in contact with the second encapsulation layer TFE2.

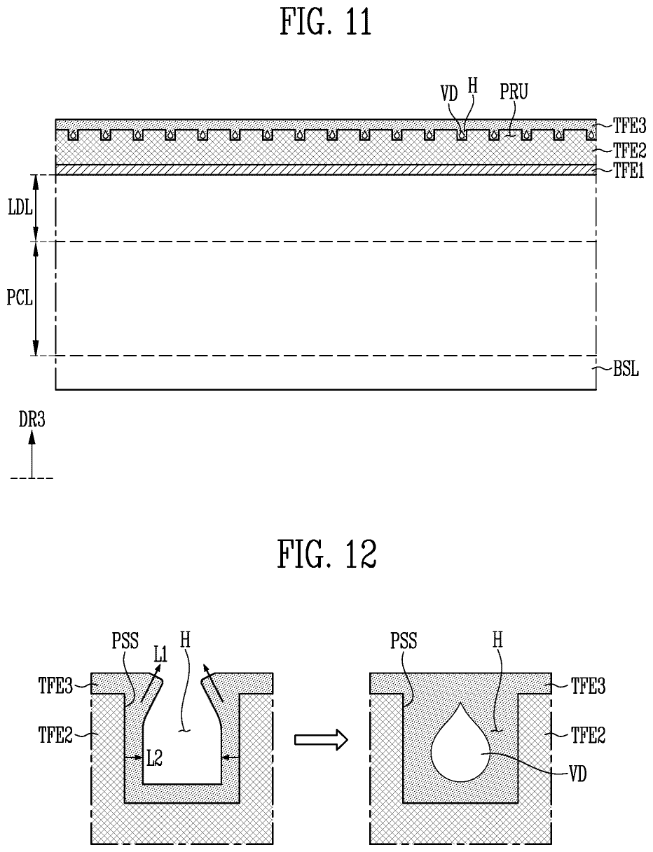

The third encapsulation layer TFE3 may include a void VD. The void VD may be a hole formed during the process of depositing the third encapsulation layer TFE3. The void VD may be located within the opening H defined by the second encapsulation layer TFE2. This will be described later with reference to FIG. 12.

The third encapsulation layer TFE3 located on a side surface PSS of the protrusion PRU may have a generally non-uniform thickness. At least a portion of the third encapsulation layer TFE3 may have a non-uniform thickness. For example, the third encapsulation layer TFE3 located on the side surface PSS of the protrusion PRU may have a thickness that increases from the center toward the outside. For example, when defining the thickness in a direction perpendicular to the side surface PSS of the protrusion PRU (for example, the first direction DR1 or the second direction DR2), the third encapsulation layer TFE3 may have a greater thickness at an edge of the side surface PSS of the protrusion PRU than at the center. For example, when viewed from a direction in which the plane in which the base layer BSL is located extends (the first direction DR1 or second direction DR2), the third encapsulation layer TFE3 overlapping the side surface PSS of the protrusion PRU may have a non-uniform thickness.

As the third encapsulation layer TFE3 includes the void VD and the third encapsulation layer TFE3 is located below the fourth encapsulation layer TFE4, the encapsulation layer TFE may relieve stress applied to the fourth encapsulation layer TFE4 when the display device DD is bent. The encapsulation layer TFE may relieve stress applied to the display device DD, thereby relatively reducing the risk of cracks forming in the encapsulation layer TFE. Accordingly, the encapsulation layer TFE may relatively improve the reliability of the display device DD by relatively reducing the defect rate of the display device DD.

The third encapsulation layer TFE3 may have a thinner thickness than the fourth encapsulation layer TFE4. The thickness of the third encapsulation layer TFE3 may be defined as an average thickness of the third encapsulation layer TFE3. The thickness of the third encapsulation layer TFE3 may include the thickness of the third encapsulation layer TFE3 that does not overlap the opening H and the thickness of the third encapsulation layer TFE3 formed within the opening H. The third encapsulation layer TFE3 may have a thickness of about 5 Å to about 15 Å. As the third encapsulation layer TFE3 has a thinner thickness than the fourth encapsulation layer TFE4, the thickness of the display device DD may not be excessively increased and the light output efficiency of the light emitting element LD may not be reduced.

The third encapsulation layer TFE3 may include an inorganic material. For example, the third encapsulation layer TFE3 may include at least one of silicon nitride (SiNx), silicon oxide (SiOx), silicon oxynitride (SiOxNy), or aluminum oxide (AIOx).

The fourth encapsulation layer TFE4 may be located on the third encapsulation layer TFE3. The fourth encapsulation layer TFE4 may entirely cover the third encapsulation layer TFE3.

The fourth encapsulation layer TFE4 may have a flat surface. For example, upper and lower surfaces of the fourth encapsulation layer TFE4 may be flat. The lower surface of the fourth encapsulation layer TFE4 may face the upper surface of the third encapsulation layer TFE3. The lower surface of the fourth encapsulation layer TFE4 may be a surface in contact with the third encapsulation layer TFE3.

The fourth encapsulation layer TFE4 may have a generally uniform thickness. The fourth encapsulation layer TFE4 may have a greater thickness than the third encapsulation layer TFE3. The fourth encapsulation layer TFE4 may have a thinner thickness than the second encapsulation layer TFE2.

The fourth encapsulation layer TFE4 may include an inorganic material. For example, the fourth encapsulation layer TFE4 may include at least one of silicon nitride (SiNx), silicon oxide (SiOx), silicon oxynitride (SiOxNy), or aluminum oxide (AIOx).

The fourth encapsulation layer TFE4 may have a density lower than or equal to that of the third encapsulation layer TFE3. For example, when observed through a transmission electron microscope (TEM), a membrane (or layer) density of the third encapsulation layer TFE3 may be higher than or equal to that of the fourth encapsulation layer TFE4. According to some embodiments of the present disclosure, as the third encapsulation layer TFE3 has a membrane density higher than or equal to that of the fourth encapsulation layer TFE4, the adhesion between the third encapsulation layer TFE3 and the fourth encapsulation layer TFE4 can be strengthened.

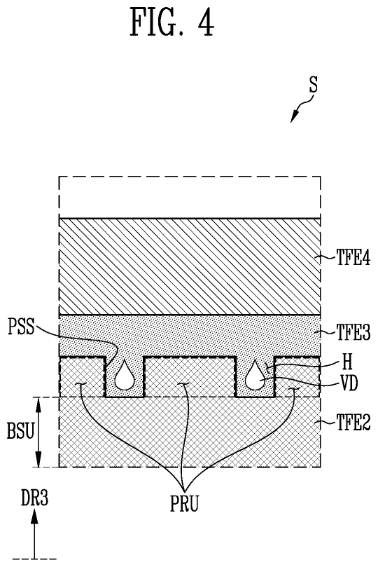

Hereinafter, a method of manufacturing the display device DD will be described with reference to FIGS. 5 to 13. Contents that overlap with the foregoing content may not be repeated.

FIG. 5 is a flow chart illustrating a method of manufacturing of a display device according to some embodiments. Although FIG. 5 illustrates various operations in a method of manufacturing a display device, embodiments according to the present disclosure are not limited thereto, and according to some embodiments the method may include additional operations, or fewer operations, or the order of operations may vary unless otherwise stated or implied, without departing from the spirit and scope of embodiments according to the present disclosure.

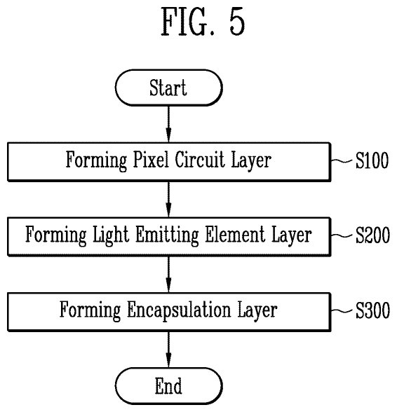

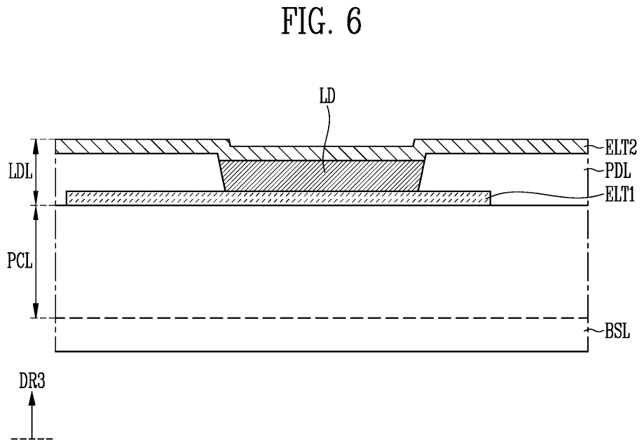

FIG. 6 is a cross-sectional view schematically illustrating the method of manufacturing the display device according to operations S100 and S200. FIG. 7 is a flow chart illustrating further details of an operation S300 of FIG. 5. Although FIG. 7 illustrates various operations in a method of manufacturing a display device, embodiments according to the present disclosure are not limited thereto, and according to some embodiments the method may include additional operations, or fewer operations, or the order of operations may vary unless otherwise stated or implied, without departing from the spirit and scope of embodiments according to the present disclosure.

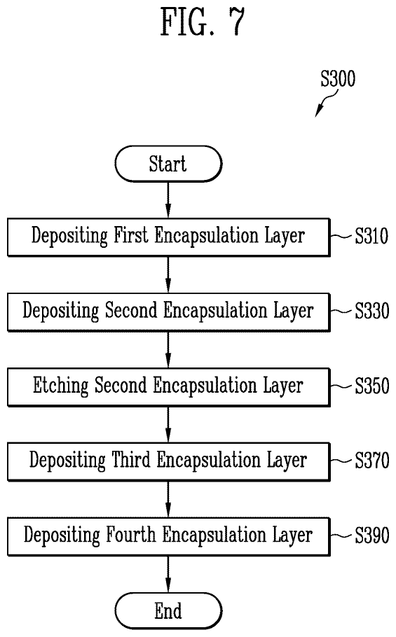

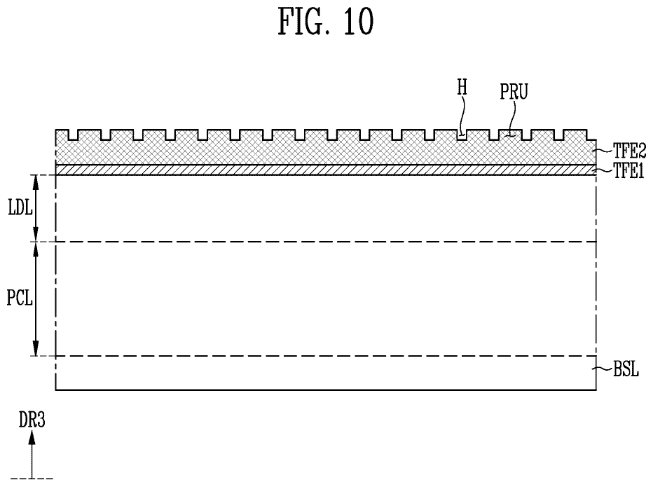

FIGS. 8, 9, 10, 11, 12, and 13 are cross-sectional views schematically illustrating the method of manufacturing the display device according to some embodiments. For clear explanation, FIG. 12 is an enlarged cross-sectional view of an area of FIG. 11 and schematically shows operations for depositing the third encapsulation layer TFE3.

Referring to FIG. 5, the method of manufacturing the display device DD may include forming a pixel circuit layer (S100), forming a light emitting element layer (S200), and forming an encapsulation layer (S300).

Referring to FIG. 6, in the forming the pixel circuit layer (S100), a pixel circuit layer PCL including a pixel circuit for driving light emitting elements LD may be formed on a base layer BSL. The pixel circuit layer PCL may be formed to include conductive layers and insulating layers located between the conductive layers.

According to some embodiments, components located on the base layer BSL may be formed through conventional patterning processes (for example, a photolithography process and the like) using masks, unless otherwise specified.

In the present disclosure, as a process for depositing components of the display device DD, one or more of a CVD (Chemical Vapor Deposition) process and an ALD (Atomic Layer Deposition) process may be used, unless otherwise specified. In the present disclosure, as an etching process, one or more of a wet etching process and a dry etching process may be used, unless otherwise specified. However, the present disclosure is not limited to specific examples.

The forming the light emitting element layer (S200) may refer to forming layers other than the encapsulation layer TFE in the display element layer DPL described above.

The forming the light emitting element layer (S200) may include forming a first electrode ELT1. The first electrode ELT1 may be formed on the pixel circuit layer PCL. According to some embodiments, the first electrode ELT1 may be deposited on the pixel circuit layer PCL and then etched to expose at least a portion of the pixel circuit layer PCL.

The forming the light emitting element layer (S200) may include forming a pixel defining layer PDL. The pixel defining layer PDL may be formed on the pixel circuit layer PCL. The pixel defining layer PDL may be deposited on the pixel circuit layer PCL and the first electrode ELT1, and the pixel defining layer PDL may be etched to expose at least a portion of the first electrode ELT1. The pixel defining layer PDL may be etched to overlap the remaining portion of the first electrode ELT1 when viewed on a plane.

The forming the light emitting element layer (S200) may include forming a light emitting element LD. The light emitting element LD may be located (or deposited) between pixel defining layers PDL. The light emitting element LD may be located (or deposited) within an area defined by the pixel defining layer PDL.

The forming the light emitting element layer (S200) may include forming a second electrode ELT2. The second electrode ELT2 may be deposited on the light emitting element LD and the pixel defining layer PDL.

Referring to FIG. 7, the forming the encapsulation layer (S300) may include depositing a first encapsulation layer (S310), depositing a second encapsulation layer (S330), etching the second encapsulation layer (S350), depositing a third encapsulation layer (S370), and depositing a fourth encapsulation layer (S390).

Referring to FIG. 8, the depositing the first encapsulation layer (S310) may correspond to forming a first encapsulation layer TFE1. In the depositing the first encapsulation layer (S310), the first encapsulation layer TFE1 may be formed on the light emitting element layer LDL. The first encapsulation layer TFE1 may be deposited on the light emitting element layer LDL. The first encapsulation layer TFE1 may cover the light emitting element layer LDL. The first encapsulation layer TFE1 may be deposited on the second electrode ELT2.

Forming a second encapsulation layer TFE2 may include depositing the second encapsulation layer (S330) and etching the second encapsulation layer (S350).

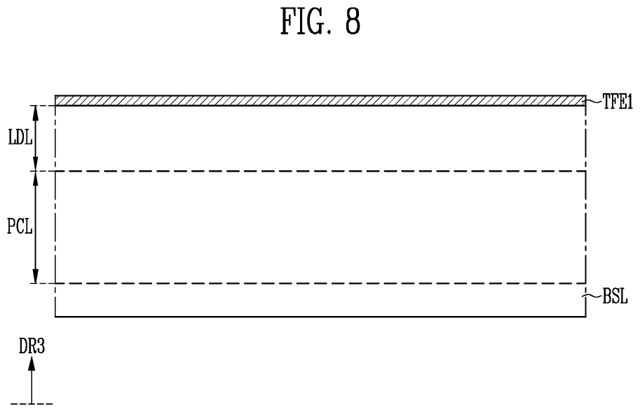

Referring to FIG. 9, in the depositing the second encapsulation layer (S330), a base encapsulation layer B_TFE2 may be deposited on the first encapsulation layer TFE1. The base encapsulation layer B_TFE2 may cover the first encapsulation layer TFE1. The base encapsulation layer B_TFE2 may be the second encapsulation layer TFE2 before a protrusion PRU is formed, and may be the second encapsulation layer TFE2 before plasma treatment.

The base encapsulation layer B_TFE2 may have a greater thickness than the first encapsulation layer TFE1.

The base encapsulation layer B_TFE2 may include at least one of an acrylic resin, an epoxy resin, a phenol resin, a polyamide resin, or a polyimide resin.

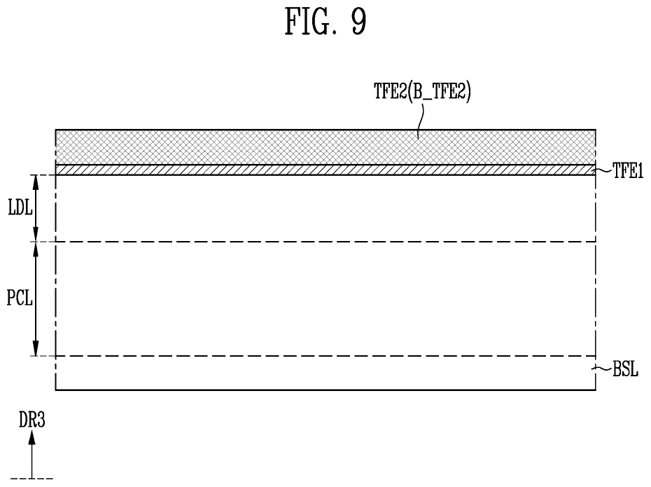

Referring to FIG. 10, the etching the second encapsulation layer (S350) may include arranging a mask on the base encapsulation layer B_TFE2. The mask may be located on the base encapsulation layer B_TFE2. The mask may have a mask pattern corresponding to the protrusion PRU. For example, the mask pattern may overlap an opening H when viewed on a plane, and the mask may expose at least a portion of the base encapsulation layer B_TFE2.

The etching the second encapsulation layer (S350) may include exposing the base encapsulation layer B_TFE2 to plasma. The base encapsulation layer B_TFE2 may be exposed to the plasma. At least a portion of the base encapsulation layer B_TFE2 exposed to the outside may be exposed to the plasma. At least a portion of a surface (for example, an upper surface) of the base encapsulation layer B_TFE2 may be exposed to the plasma, and at least a portion of the surface of the base encapsulation layer B_TFE2 may be etched. For example, at least a portion of the base encapsulation layer B_TFE2 exposed to the outside by the mask pattern may be etched.

The base encapsulation layer B_TFE2 may be etched to form the second encapsulation layer TFE2. The base encapsulation layer B_TFE2 may be etched to form the protrusion PRU and the opening H.

Referring to FIGS. 11 and 12, the forming the third encapsulation layer TFE3 may correspond to the depositing the third encapsulation layer (S370). In the depositing the third encapsulation layer (S370), the third encapsulation layer TFE3 may be formed on the second encapsulation layer TFE2. The third encapsulation layer TFE3 may be deposited on the second encapsulation layer TFE2.

The third encapsulation layer TFE3 may entirely cover the second encapsulation layer TFE2. At least a portion of the third encapsulation layer TFE3 may be formed within the opening H. At least a portion of the third encapsulation layer TFE3 may be deposited within the opening H.

Since the second encapsulation layer TFE2 includes the protrusion PRU, an upper surface of the second encapsulation layer TFE2 may have a step difference. Accordingly, when the third encapsulation layer TFE3 is deposited on the second encapsulation layer TFE2, the third encapsulation layer TFE3 may be deposited at a different deposition rate in some areas than in other areas. For example, the third encapsulation layer TFE3 may be deposited in a relatively smaller amount in some areas than in other areas. For example, an outer region of a side surface PSS of the protrusion PRU may be deposited at a first deposition rate L1, and a central region of the side surface PSS of the protrusion PRU may be deposited at a second deposition rate L2 different from the first deposition rate L1.

The first deposition rate L1 may be faster than the second deposition rate L2. Accordingly, the third encapsulation layer TFE3 located on the side surface PSS of the protrusion PRU may have a thickness that increases from the center toward the outside, and a hole (that is, a void VD) may be formed during the process of depositing the third encapsulation layer TFE3.

The third encapsulation layer TFE3 according to some embodiments of the present disclosure may not be separately etched in the process of forming the void VD. Accordingly, the void VD having a uniform shape can be formed in the third encapsulation layer TFE3, and stress applied to the encapsulation layer TFE can be relieved.

Voids VD may be formed entirely throughout the display area DA and the non-display area NDA. Accordingly, according to the display device DD of the present disclosure, stress can be relieved in all areas of the display device DD, and the reliability of the display device DD can be relatively improved.

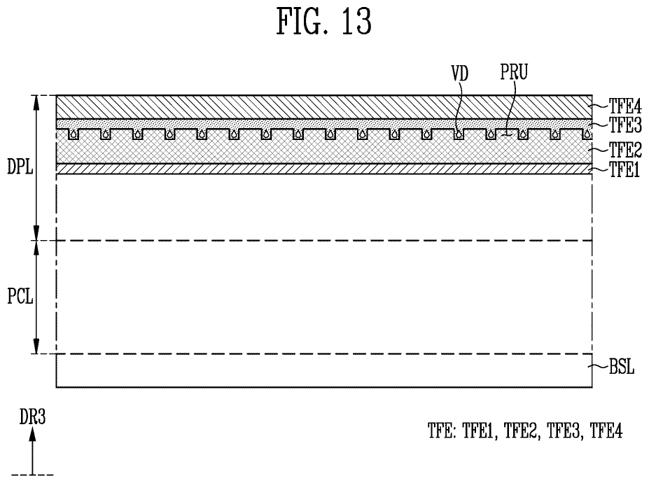

Referring to FIG. 13, in the depositing the fourth encapsulation layer (S390), the fourth encapsulation layer TFE4 may be formed on the third encapsulation layer TFE3. The fourth encapsulation layer TFE4 may be deposited on the third encapsulation layer TFE3. The fourth encapsulation layer TFE4 may entirely cover the third encapsulation layer TFE3.

The fourth encapsulation layer TFE4 may be deposited after the void VD is formed. Accordingly, the fourth encapsulation layer TFE4 may not be filled into the void VD.

According to some embodiments of the present disclosure, a display device capable of relatively reducing a defect rate and a method manufacturing the same can be provided.

As described above, the aspects of some embodiments of the present disclosure have been disclosed through the detailed description and the drawings. However, those skilled in the art or those of ordinary skill in the art will appreciate that various modifications and changes are possible without departing from the spirit and technical scope of the present disclosure as set forth in the claims below.

Therefore, the technical protection scope of the present disclosure is not limited to the detailed description described in the specification, but should be determined by the appended claims, and their equivalents.

What is claimed is:

1. A display device comprising:
a light emitting element; and
an encapsulation layer on the light emitting element,
wherein the encapsulation layer includes:
a first encapsulation layer;
a second encapsulation layer on the first encapsulation layer;
a third encapsulation layer on the second encapsulation layer; and
a fourth encapsulation layer on the third encapsulation layer,
wherein the third encapsulation layer includes a void.

2. The display device of claim 1, wherein the second encapsulation layer includes an organic material, and
wherein the first encapsulation layer, the third encapsulation layer, and the fourth encapsulation layer include an inorganic material.

3. The display device of claim 1, wherein the second encapsulation layer includes:
a base portion; and
a protrusion protruding from the base portion in a normal direction of a plane in which the display device is located.

4. The display device of claim 3, further comprising:
an opening adjacent to the protrusion.

5. The display device of claim 1, wherein the second encapsulation layer includes an upper surface having uneven portions.

6. The display device of claim 4, wherein at least a portion of the third encapsulation layer is within the opening, and
wherein the void is within the opening.

7. The display device of claim 1, wherein the third encapsulation layer has a density higher than or equal to a density of the fourth encapsulation layer.

8. The display device of claim 1, wherein the fourth encapsulation layer has a greater thickness than the third encapsulation layer.

9. The display device of claim 8, wherein the third encapsulation layer has a thickness in a range of 5 Å to 15 Å.

10. The display device of claim 3, wherein the third encapsulation layer overlapping a side surface of the protrusion has an uneven thickness.

11. The display device of claim 1, wherein the first encapsulation layer contacts the second encapsulation layer,
wherein the second encapsulation layer contacts the third encapsulation layer, and
wherein the third encapsulation layer contacts the fourth encapsulation layer.

12. The display device of claim 1, wherein the fourth encapsulation layer is not filled into the void.

13. A method of manufacturing a display device comprising:
forming a light emitting element layer; and
forming an encapsulation layer on the light emitting element layer,
wherein the forming the encapsulation layer includes:
forming a first encapsulation layer;
forming a second encapsulation layer on the first encapsulation layer;
forming a third encapsulation layer on the second encapsulation layer; and
forming a fourth encapsulation layer on the third encapsulation layer,
wherein the forming the third encapsulation layer includes forming a void in the third encapsulation layer.

14. The method of claim 13, wherein the second encapsulation layer includes an organic material,
wherein the first encapsulation layer, the third encapsulation layer, and the fourth encapsulation layer include an inorganic material,
wherein the first encapsulation layer contacts the second encapsulation layer,
wherein the second encapsulation layer contacts the third encapsulation layer, and
wherein the third encapsulation layer contacts the fourth encapsulation layer.

15. The method of claim 13, wherein the forming the second encapsulation layer includes:
forming a base encapsulation layer on the first encapsulation layer;
arranging a mask on the base encapsulation layer; and
exposing the base encapsulation layer to plasma,
wherein at least a portion of an upper surface of the base encapsulation layer is etched by the plasma.

16. The method of claim 15, wherein the base encapsulation layer is etched by the plasma to form a protrusion and an opening.

17. The method of claim 15, wherein the base encapsulation layer is etched by the plasma so that an upper surface of the second encapsulation layer has uneven portions.

18. The method of claim 16, wherein the void is within the opening.

19. The method of claim 13, wherein the forming the third encapsulation layer includes depositing the third encapsulation layer on the second encapsulation layer, and
wherein the third encapsulation layer is deposited at a different rate in some areas than in other areas.

20. The method of claim 13, wherein the third encapsulation layer has a thickness in a range of 5 Å to 15 Å.
